(19) United States
(12) Patent Application Publication
(10) Pub. No.: US 2023/0017629 A1
(43) Pub. Date: Jan. 19, 2023

(54) PANEL DRIVING ARCHITECTURE, DRIVING METHOD, AND DISPLAY DEVICE

(71) Applicant: CHONGQING KONKA PHOTOELECTRIC TECHNOLOGY RESEARCH INSTITUTE CO., LTD., Chongqing (CN)

(72) Inventors: Xiaolin LIANG, Chongqing (CN); Jiang CAO, Chongqing (CN); Xiaoteng HUANG, Chongqing (CN); Shengyi LI, Chongqing (CN); Yang CHEN, Chongqing (CN)

(21) Appl. No.: 17/951,270

(22) Filed: Sep. 23, 2022

Related U.S. Application Data
(63) Continuation of application No. PCT/CN2021/105813, filed on Jul. 12, 2021.

(51) Int. Cl. G09G 3/32

(52) U.S. Cl. CPC G09G 3/32; G09G 2330/021; G09G 2300/0828; G09G 2310/0297

(57) ABSTRACT

A panel driving architecture is provided in the disclosure. The panel driving architecture includes a circuit board module and a panel module electrically coupled with the circuit board module. The circuit board module includes a power management circuit and a signal management circuit. The power management circuit is electrically coupled with the panel module and the signal management circuit. The power management circuit is configured to provide an operating voltage for the panel module and the signal management circuit. The signal management circuit is electrically coupled with the panel module and configured to: provide a first scanning signal, convert the first scanning signal into a second scanning signal, output the second scanning signal to the panel module, provide a first data signal, convert the first data signal into a second data signal containing a data signal, and output the second data signal to the panel module.

### CROSS-REFERENCE TO RELATED APPLICATIONS

This application is a continuation application of International Application No. PCT/CN2021/105813, filed Jul. 12, 2021, the entire disclosure of which is incorporated herein by reference.

### TECHNICAL FIELD

This application relates to the technical field of display, and in particular, to a panel driving architecture, a driving method for a panel driving architecture, and a display device with the panel driving architecture.

### BACKGROUND

At present, in the light-emitting diode (LED) display industry, panel driving integrated circuits (ICs) are used for driving in most conventional driving solutions for LED panels. Currently, due to a global driving chip shortage, a plenty of companies have no driving chip or lead times of driving chips are extended.

Therefore, how to solve extended lead times of driving chips or no supply of driving chips due to a driving chip shortage becomes an urgent problem for those skilled in the art.

In view of above disadvantages in the related art, a panel driving architecture, a driving method for a panel driving architecture, and a display device with the panel driving architecture are provided in the disclosure, which aim to solve problems of extended lead times of driving chips or no supply of driving chips due to a driving chip shortage.

### SUMMARY

A panel driving architecture is provided. The panel driving architecture includes a circuit board module and a panel module electrically coupled with the circuit board module, where the circuit board module includes a power management circuit and a signal management circuit. The power management circuit is electrically coupled with the panel module and the signal management circuit. The power management circuit is configured to provide an operating voltage for the panel module and the signal management circuit. The signal management circuit is electrically coupled with the panel module and configured to: provide a first scanning signal, convert the first scanning signal into a second scanning signal, output the second scanning signal to the panel module, provide a first data signal, convert the first data signal into a second data signal containing a data signal, and output the second data signal to the panel module. The panel module is configured to drive pixels to display according to the data signal.

It can be seen that, in the panel driving architecture provided in the disclosure, the signal management circuit is used to replace a panel driving chip, which reduces a demand for the panel driving chip. As such, the panel driving architecture is provided in the disclosure, which solves problems of extended lead times for driving chips or no supply of driving chips due to a driving chip shortage, and increases a panel production efficiency.

Optionally, the signal management circuit includes a signal configuration unit, a first signal conversion unit, a second signal conversion unit, and a third signal conversion unit. The signal configuration unit is electrically coupled with the power management circuit, the first signal conversion unit, the second signal conversion unit, and the third signal conversion unit. The signal configuration unit is configured to: provide the first scanning signal, transmit the first scanning signal to the first signal conversion unit and the second signal conversion unit, provide the first data signal, and transmit the first data signal to the third signal conversion unit.

Optionally, the first signal conversion unit is electrically coupled between the signal configuration unit and the panel module. The first signal conversion unit is configured to convert the first scanning signal transmitted by the signal configuration unit into the second scanning signal, and output the second scanning signal to the panel module. The second signal conversion unit is electrically coupled between the signal configuration unit and the panel module. The second signal conversion unit is configured to convert the first scanning signal transmitted by the signal configuration unit into the second scanning signal, and output the second scanning signal to the panel module. The third signal conversion unit is electrically coupled between the signal configuration unit and the panel module. The third signal conversion unit is configured to convert the first data signal transmitted by the signal configuration unit into the second data signal, and output the second data signal to the panel module.

Optionally, the signal configuration unit is a field-programmable gate array (FPGA).

Optionally, each of the first signal conversion unit, the second signal conversion unit, and the third signal conversion unit is a digital-to-analog convertor (DAC). Each of the first scanning signal and the first data signal is a digital signal. Each of the second scanning signal and the second data signal is an analog signal.

Optionally, the panel module includes a pixel driving circuit and a signal transmission circuit. The signal transmission circuit is electrically coupled between the pixel driving circuit and the signal management circuit. The signal transmission circuit is configured to: receive the second data signal which is transmitted by the signal management circuit and contains the data signal and a channel-select signal, select corresponding signal transmission channels according to the channel-select signal, and transmit the data signal to the pixel driving circuit.

Optionally, the panel module further includes a first drive circuit and a second drive circuit. Each of the first drive circuit and the second drive circuit is electrically coupled with the pixel driving circuit and the signal management circuit. Each of the first drive circuit and the second drive circuit is configured to: transmit a corresponding drive signal to the pixel driving circuit, and receive the second scanning signal outputted from the signal management circuit.

Optionally, each of the first drive circuit and the second drive circuit consists of a gate driver on array (GOA) circuit and an emission driver on array (EOA) circuit.

Optionally, the signal transmission circuit includes multiple signal transmission units. Each of the multiple signal transmission units is electrically coupled between the third signal conversion unit and the pixel driving circuit. Each of the multiple signal transmission units is configured to: receive the data signal and the channel-select signal transmitted by the third signal conversion unit, select corresponding signal transmission channels according to the channel-select signal, and transmit the data signal to the pixel driving circuit.

Optionally, each of the multiple signal transmission units is a multiplexer (MUX).

It can be seen that, in the panel driving architecture provided in the disclosure, the signal configuration unit is configured to transmit the digital signal and the channel-select signal to the first signal conversion unit through a manner of programing. The signal configuration unit is used to replace a panel driving chip, reducing a demand for the panel driving chip. As such, the panel driving architecture is provided in the disclosure, which solves problems of extended lead times for driving chips or no supply of driving chips due to a driving chip shortage, and increases a panel production efficiency.

A driving method for a panel driving architecture is further provided in the disclosure in the same way. The driving method is for driving the panel driving architecture above and includes the following. The power management circuit transmits an operating voltage to the signal configuration unit and the pixel driving circuit. The signal configuration unit transmits the first scanning signal to the first signal conversion unit and the second signal conversion unit, and transmits the first data signal to the third signal conversion unit. The first signal conversion unit and the second signal conversion unit convert the first scanning signal into the second scanning signal, and transmit the second scanning signal to the first drive circuit and the second drive circuit respectively. The third signal conversion unit converts the first data signal into the second data signal containing the data signal and the channel-select signal, and transmits the second data signal to the multiple signal transmission units. The multiple signal transmission units receive the data signal and the channel-select signal in the second data signal, select corresponding signal transmission channels according to the channel-select signal, and transmit the data signal to the pixel driving circuit, where the pixel driving circuit is electrically coupled with the multiple signal transmission units.

It can be seen that, in the driving method for a panel driving architecture provided in the disclosure, the signal configuration unit transmits the digital signal and the channel-select signal to the first signal conversion unit through a manner of programing. The FPGA is used to replace a panel driving chip, reducing a demand for the panel driving chip. As such, the panel driving architecture is provided in the disclosure, which solves problems of extended lead times for driving chips or no supply of driving chips due to a driving chip shortage, and increases a panel production efficiency.

A display device is further provided in the disclosure in the same way. The display device includes a display panel and a panel driving architecture. The panel driving architecture includes a circuit board module and a panel module electrically coupled with the circuit board module. The circuit board module includes a power management circuit and a signal management circuit. The power management circuit is electrically coupled with the panel module and the signal management circuit. The power management circuit is configured to provide an operating voltage for the panel module and the signal management circuit. The signal management circuit is electrically coupled with the panel module and configured to: provide a first scanning signal, convert the first scanning signal into a second scanning signal, output the second scanning signal to the panel module, provide a first data signal, convert the first data signal into a second data signal containing a data signal, and output the second data signal to the panel module. The panel module is configured to drive pixels to display according to the data signal.

It can be seen that, in the display device provided in the disclosure, the signal configuration unit is configured to transmit the digital signal and the channel-select signal to the first signal conversion unit through a manner of programing. The FPGA is used to replace a panel driving chip, reducing a demand for the panel driving chip. As such, the panel driving architecture is provided in the disclosure, which solves problems of extended lead times for driving chips or no supply of driving chips due to a driving chip shortage, and increases a panel production efficiency.

Optionally, the signal management circuit includes a signal configuration unit, a first signal conversion unit, a second signal conversion unit, and a third signal conversion unit. The signal configuration unit is electrically coupled with the power management circuit, the first signal conversion unit, the second signal conversion unit, and the third signal conversion unit. The signal configuration unit is configured to: provide the first scanning signal, transmit the first scanning signal to the first signal conversion unit and the second signal conversion unit, provide the first data signal, and transmit the first data signal to the third signal conversion unit.

Optionally, the first signal conversion unit is electrically coupled between the signal configuration unit and the panel module. The first signal conversion unit is configured to convert the first scanning signal transmitted by the signal configuration unit into the second scanning signal, and output the second scanning signal to the panel module. The second signal conversion unit is electrically coupled between the signal configuration unit and the panel module. The second signal conversion unit is configured to convert the first scanning signal transmitted by the signal configuration unit into the second scanning signal, and output the second scanning signal to the panel module. The third signal conversion unit is electrically coupled between the signal configuration unit and the panel module. The third signal conversion unit is configured to convert the first data signal transmitted by the signal configuration unit into the second data signal, and output the second data signal to the panel module.

Optionally, the signal configuration unit is an FPGA.

Optionally, each of the first signal conversion unit, the second signal conversion unit, and the third signal conversion unit is a DAC. Each of the first scanning signal and the first data signal is a digital signal. Each of the second scanning signal and the second data signal is an analog signal.

Optionally, the panel module includes a pixel driving circuit and a signal transmission circuit. The signal transmission circuit is electrically coupled between the pixel driving circuit and the signal management circuit. The signal transmission circuit is configured to: receive the second data signal which is transmitted by the signal management circuit and contains the data signal and a channel-select signal, select corresponding signal transmission channels according to the channel-select signal, and transmit the data signal to the pixel driving circuit.

Optionally, the panel module further includes a first drive circuit and a second drive circuit. Each of the first drive circuit and the second drive circuit is electrically coupled with the pixel driving circuit and the signal management circuit. Each of the first drive circuit and the second drive circuit is configured to: transmit a corresponding drive signal to the pixel driving circuit, and receive the second scanning signal outputted from the signal management circuit.

Optionally, each of the first drive circuit and the second drive circuit consists of a GOA circuit and an EOA circuit.

Optionally, the signal transmission circuit includes multiple signal transmission units. Each of the multiple signal transmission units is electrically coupled between the third signal conversion unit and the pixel driving circuit. Each of the multiple signal transmission units is configured to: receive the data signal and the channel-select signal transmitted by the third signal conversion unit, select corresponding signal transmission channels according to the channel-select signal, and transmit the data signal to the pixel driving circuit.

It can be seen that, in the display device provided in the disclosure, the signal configuration unit is configured to transmit the digital signal and the channel-select signal to the first signal conversion unit through a manner of programing. The FPGA is used to replace a panel driving chip, reducing a demand for the panel driving chip. As such, the panel driving architecture is provided in the disclosure, which solves problems of extended lead times for driving chips or no supply of driving chips due to a driving chip shortage, and increases a panel production efficiency.

### BRIEF DESCRIPTION OF THE DRAWINGS

In order to describe technical solutions in implementations of the disclosure more clearly, the following will give a brief introduction to the accompanying drawings required for describing implementations. Apparently, the accompanying drawings hereinafter described are merely some implementations of the disclosure. Based on these drawings, those of ordinary skill in the art can also obtain other drawings without creative effort.

FIG. 1 is a schematic structural diagram illustrating a panel driving architecture provided in implementations of the disclosure.

FIG. 2 is a schematic circuit diagram of the panel driving architecture illustrated in FIG. 1.

FIG. 3 is a schematic circuit diagram of the panel driving architecture illustrated in FIG. 2.

FIG. 4 is a schematic diagram illustrating proportional selection logic of a signal transmission unit in the panel driving architecture illustrated in FIG. 2.

FIG. 5 is a schematic flow chart of a driving method for a panel driving architecture disclosed in implementations of the disclosure.

Reference signs in the accompanying drawings: 100—panel driving architecture; 110—circuit board module; 120—panel module; 111—power management circuit; 112—signal management circuit; 121—pixel driving circuit; 123—signal transmission circuit; 124—first drive circuit; 125—second drive circuit; 1121—signal configuration unit; 1122—first signal conversion unit; 1123—second signal conversion unit; 1125—third signal conversion unit; 1231—signal transmission unit; S1-S4—steps of a driving method; S410-S460—steps of proportional selection.

### DETAILED DESCRIPTION

For ease of understanding, the disclosure is described more completely with reference to the accompanying drawings hereinafter. The accompanying drawings illustrate preferred implementations of the disclosure. However, the disclosure can be implemented in various forms and is not limited to the implementations described herein. Rather, these implementations are provided for a more thorough and comprehensive understanding of the disclosure.

Unless otherwise defined, all technical and scientific terms used herein have the same meaning as commonly understood by those skilled in the art of the disclosure. The terms used herein in the disclosure are for merely describing implementations rather than intending to limit the disclosure.

At present, in the light-emitting diode (LED) display industry, panel driving integrated circuits (ICs) are used for driving in most conventional driving solutions for LED panels. Currently, due to a global driving chip shortage, a plenty of companies have no driving chip or lead times of driving chips are extended. In view of above, the disclosure aims to solve extended lead times of driving chips or no supply of driving chips due to a driving chip shortage, so that display panels can lighted without driving chips. Details are described in the implementations hereinafter.

A panel driving architecture, a driving method for the panel driving architecture, and a specific circuit structure of a display device with the panel driving architecture will be described in detail in solutions of the disclosure.

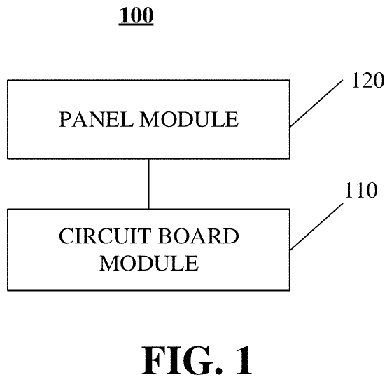

Referring to FIG. 1, FIG. 1 is a schematic structural diagram illustrating a panel driving architecture provided in the implementations of the disclosure. As illustrated in FIG. 1, a panel driving architecture 100 is provided in the disclosure. The panel driving architecture 100 may include at least a circuit board module 110 and a panel module 120. The circuit board module 110 is disposed on a side of the panel module 120 and is electrically coupled with the panel module 120. The circuit board module 110 is configured to provide an operating voltage, a drive current, and a corresponding functional signal for the panel module 120.

In the implementations of the disclosure, no chip on film (COF) is required between the circuit board module 110 and the panel module 120 since no driving chip is disposed for achieving a connection between the circuit board module 110 and the panel module 120. It simply needs a flexible printed circuit (FPC) for achieving the connection between the circuit board module 110 and the panel module 120. Similarly, a press-fit connection is achieved through a bonding process.

It can be understood that, the panel driving architecture 100 may be used to an electronic device which has, for example, a personal digital assistant (PDA) and/or a music player function, such as a phone, a tablet computer, and a wearable electronic device with a wireless communication function (e.g., a smart watch or a smart wristband). The above electronic device may also be other electronic apparatuses, such as a laptop with a touch-sensitive surface (e.g., a touch panel). In some implementations, the electronic device can have a communication function, i.e., the electronic device can communicate with a network through 2^{nd} generation mobile communication technical specifications (2G), 3^{rd} generation mobile communication technical specifications (3G), 4^{th} generation mobile communication technical specifications (4G), 5^{th} generation mobile communication technical specifications (5G), a wireless local area network (W-LAN), or a future possible communication manner, which will not be limited in the implementations of the disclosure for sake of simplicity.

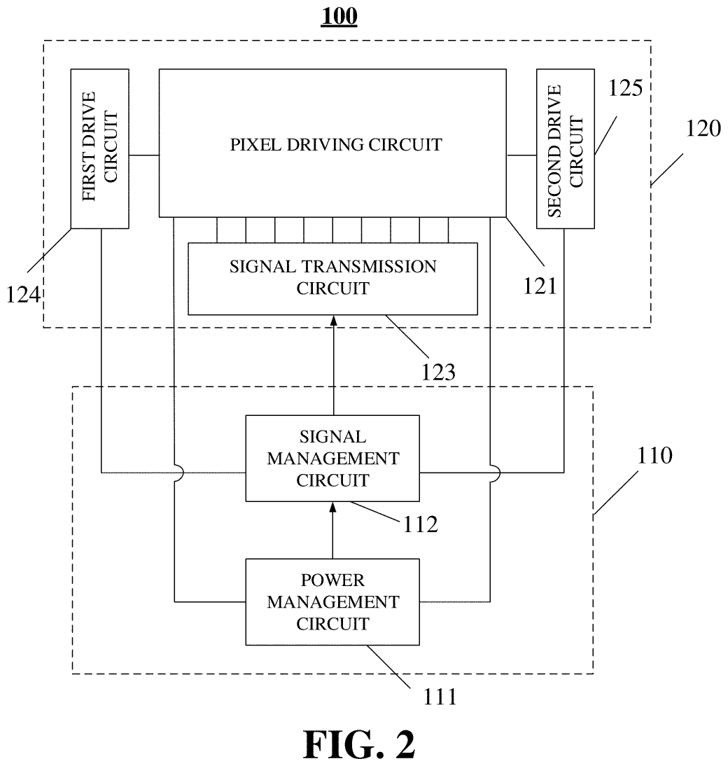

Referring to FIG. 2, FIG. 2 is a schematic circuit diagram of the panel driving architecture illustrated in FIG. 1. In the implementations of the disclosure, as illustrated in FIG. 2, the circuit board module 110 provided in the disclosure may include at least a power management circuit 111 and a signal management circuit 112. The panel module 120 may include at least a pixel driving circuit 121, a signal transmission circuit 123, a first drive circuit 124, and a second drive circuit 125.

The power management circuit 111 is electrically coupled with the pixel driving circuit 121 and the signal management circuit 112. The power management circuit 111 is configured to provide an operating voltage for the pixel driving circuit 121 and the signal management circuit 112. In the implementations of the disclosure, the power management circuit 111 may be a power management integrated circuit (PMIC), which is mainly responsible for conversion, distribution, detection, and other power managements of electrical energy in a circuit system. For example, in the implementations of the disclosure, the power management circuit 111 can provide an electroluminescence voltage of device (ELVDD) or an electroluminescence voltage of series (ELVSS) for the panel module 120, and provide an operating voltage for the signal management circuit 112.

The signal management circuit 112 is electrically coupled with the first drive circuit 124, the second drive circuit 125, and the signal transmission circuit 123. The signal management circuit 112 is configured to: provide a first scanning signal, convert the first scanning signal into a second scanning signal, output the second scanning signal to the first drive circuit 124 and the second drive circuit 125, provide a first data signal, convert the first data signal into a second data signal, and output the second data signal to the signal transmission circuit 123.

In the implementations of the disclosure, the first scanning signal is a digital signal, and the second scanning signal is an analog signal, which includes but is not limited to: a start timing of vertical (STV) signal and a clock (CLK) signal. The first data signal is a digital signal, and the second data signal is also an analog signal, which includes but is not limited to: a data signal (i.e., a red-blue-green (RGB) data signal) and a channel-select signal.

The pixel driving circuit 121 is electrically coupled with the first drive circuit 124, the second drive circuit 125, the signal transmission circuit 123, and the power management circuit 111. The pixel driving circuit 121 is configured to: receive a drive signal transmitted by the first drive circuit 124 and the second drive circuit 125, and drive RGB pixels to display according to the second data signal that is transmitted by the signal transmission circuit 123 through different lines.

In the implementations of the disclosure, the pixel driving circuit 121 may be 3T1C, 4T1C, 7T1C, or the other driving circuits.

Each of the first drive circuit 124 and the second drive circuit 125 is electrically coupled with the pixel driving circuit 121 and the signal management circuit 112. Each of the first drive circuit 124 and the second drive circuit 125 is configured to: transmit a corresponding drive signal to the pixel driving circuit 121, and receive the second scanning signal outputted from the signal management circuit 112. In the implementation, the first drive circuit 124 and the second drive circuit 125 are respectively disposed at two opposite sides of the pixel driving circuit 121.

In the implementations of the disclosure, each of the first drive circuit 124 and the second drive circuit 125 consists of a gate driver on array (GOA) circuit and an emission driver on array (EOA) circuit.

The signal transmission circuit 123 is electrically coupled between the pixel driving circuit 121 and the signal management circuit 112. The signal transmission circuit 123 is configured to: receive the data signal and the channel-select signal transmitted by the signal management circuit 112, select corresponding signal transmission channels according to the channel-select signal, and transmit the data signal to the pixel driving circuit 121 through different lines. Here, the pixel driving circuit 121 receives the data signal transmitted by the signal transmission circuit 123 and drives the RGB pixels to display according to the data signal.

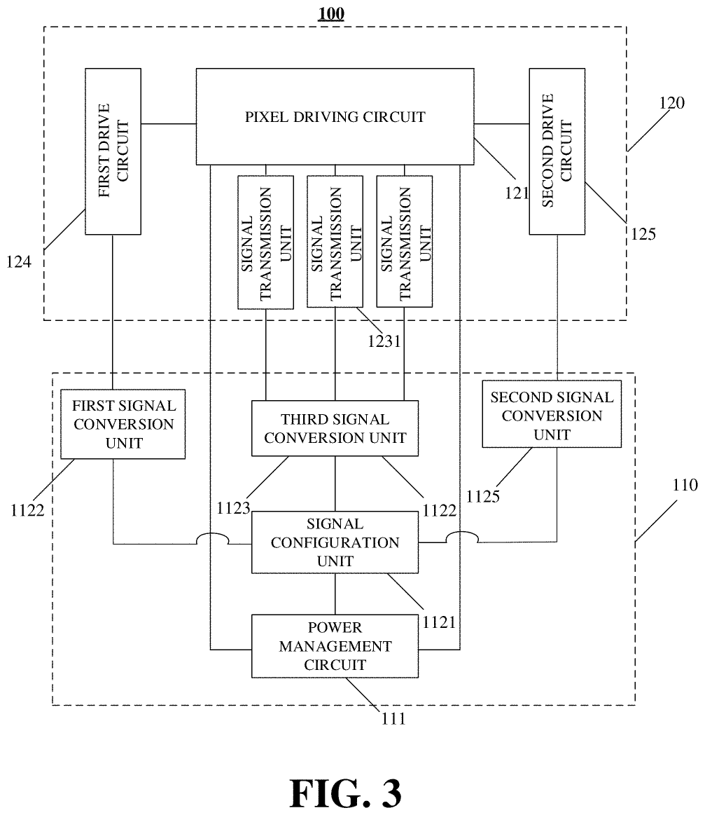

Referring to FIG. 3, FIG. 3 is a schematic circuit diagram of the panel driving architecture illustrated in FIG. 2. As illustrated in FIG. 3, the signal management circuit 112 in the circuit board module 110 provided in the disclosure includes a signal configuration unit 1121, a first signal conversion unit 1122, a second signal conversion unit 1123, and a third signal conversion unit 1125. The signal transmission circuit 123 in the panel module 120 includes multiple signal transmission units 1231.

The signal configuration unit 1121 is electrically coupled with the power management circuit 111, the first signal conversion unit 1122, the second signal conversion unit 1123, and the third signal conversion unit 1125. The signal configuration unit 1121 is configured to: provide the first scanning signal, transmit the first scanning signal to the first signal conversion unit 1122 and the second signal conversion unit 1123, provide the first data signal, and transmit the first data signal to the third signal conversion unit 1125. Each of the first scanning signal and the first data signal is a digital signal.

In the implementations of the disclosure, the signal configuration unit 1121 can be a field-programmable gate array (FPGA). In some implementations, the signal configuration unit 1121 provides the digital signal and the channel-select signal for the first signal conversion unit 1122, the second signal conversion unit 1123, and the third signal conversion unit 1125 through a manner of programing.

The first signal conversion unit 1122 is electrically coupled with the signal configuration unit 1121 and the first drive circuit 124. The first signal conversion unit 1122 is configured to convert the first scanning signal transmitted by the signal configuration unit 1121 into the second scanning signal, and output the second scanning signal to the first drive circuit 124.

The second signal conversion unit 1123 is electrically coupled with the signal configuration unit 1121 and the second drive circuit 125. The second signal conversion unit 1123 is configured to convert the first scanning signal transmitted by the signal configuration unit 1121 into the second scanning signal, and output the second scanning signal to the second drive circuit 125.

The third signal conversion unit 1125 is electrically coupled with the signal configuration unit 1121 and the multiple signal transmission units 1231 in the signal transmission circuit 123, i.e., the third signal conversion unit 1125 is electrically coupled between the signal configuration unit 1121 and the multiple signal transmission units 1231. The third signal conversion unit 1125 is configured to convert the first data signal transmitted by the signal configuration unit 1121 into the second data signal, and output the second data signal to the multiple signal transmission units 1231.

In the implementations of the disclosure, each of the second scanning signal and the second data signal is an analog signal. The second scanning signal includes but is not limited to: an STV signal and a CLK signal. The second data signal includes but is not limited to: a data signal (i.e., an RGB data signal) and a channel-select signal.

In the implementations of the disclosure, each of the first signal conversion unit 1122 and the second signal conversion unit 1123 may be a digital-to-analog convertor (DAC), and the third signal conversion unit 1125 includes multiple DACs. In the implementations of the disclosure, the number of the DACs in the third signal conversion unit 1125 corresponds to the number of the signal transmission units 1231, and each DAC in the third signal conversion unit 1125 is electrically coupled with one corresponding signal transmission unit 1231.

The multiple signal transmission units 1231 are electrically coupled with the third signal conversion unit 1125 and the pixel drive circuit 121, i.e., each of the multiple signal transmission units 1231 is electrically coupled between the third signal conversion unit 1125 and the pixel drive circuit 121. Each of the multiple signal transmission units 1231 is configured to: receive the data signal and the channel-select signal transmitted by the third signal conversion unit 1125, select corresponding signal transmission channels according to the channel-select signal, and transmit the data signal to the pixel driving circuit 121 through different lines. In this case, the pixel driving circuit 121 receives the data signal transmitted by the signal transmission circuit 123, and drives the RGB pixels to display corresponding brightness according to the signal.

In the implementation, each of the multiple signal transmission units 1231 may be a multiplexer (MUX). When the DAC has a large driving current, the MUX can be used, so that multiple columns of pixels can be driven through one data line, and the data signal can be controlled to be outputted to a pixel of a corresponding column through the MUX.

It can be understood that, in the implementations of the disclosure, a circuit of the MUX can be classified into different types with proportions such as 1:1, 1:2, 1:3, 1:6, and 1:12 according to actual designs. The disclosure is not limited to the above proportions, which are not limited herein. In addition, in specific examples, a proportion of the MUX is selected depends on data affecting resistance capacity loading (RC loading), such as a panel size, and a resolution.

In the implementations of the disclosure, MUX logic signal control is illustrated in Tables 1 to 3 for 1:3 MUX, 1:6 MUX, and 1:12 MUX, respectively.

TABLE 1
logic signal control of 1:3 MUX

| Sequence number | Control signal | Output channel |
|---|---|---|
| 1 | 001 | R1 |
| 2 | 010 | G1 |
| 3 | 011 | B1 |

TABLE 2
logic signal control of 1:6 MUX

| Sequence number | Control signal | Output channel |
|---|---|---|
| 1 | 001 | R1 |
| 2 | 010 | G1 |
| 3 | 011 | B1 |
| 4 | 100 | R2 |
| 5 | 101 | G2 |
| 6 | 110 | B2 |

TABLE 3
logic signal control of 1:12 MUX

| Sequence number | Control signal | Output channel |
|---|---|---|
| 1 | 0001 | R1 |
| 2 | 0010 | G1 |
| 3 | 0011 | B1 |
| 4 | 0100 | R2 |
| 5 | 0101 | G2 |
| 6 | 0110 | B2 |
| 7 | 0111 | R3 |
| 8 | 1001 | G3 |
| 9 | 1010 | B3 |
| 10 | 1011 | R4 |
| 11 | 1100 | G4 |
| 12 | 1101 | B4 |

It can be understood that, MUX logic signal control is not only limited to the above control solutions, there are also control solutions with other proportions in other implementations, which is not limited herein. It to be noted that, data lines can be saved with aid of a higher order MUX due to its a large driving current. For example, 1920*3=5760 data lines are required when a resolution is 1920RGB*1080, but only 480 data lines are required in a control solution where the MUX (for example, 1:12 MUX) is used.

Generally, when a COF of the driving chip is adopted, a pitch of the COF is generally 25 μm, and thus a width of the COF for a resolution of 1920RGB*1080 is 25*1920*3=144000 μm. But if adopting an FPC for connection, a pitch of the FPC is generally 75 μm, and a width of the FPC for the resolution of 1920RGB*1080 is 75*1920*3=432000 μm without the MUX. The width of the FPC is too wide compared to the COF, which is not conducive to a bonding process of a product. But if the MUX (for example, 1:12 MUX) is adopted in a control solution, the width of the FPC is only 75*1920*3/12=36000 μm, and the width of the FPC is not excessively wide compared to the COF, which makes no adverse effect on product design and the bonding process.

It can be seen that, in the panel driving architecture provided in the disclosure, the signal configuration unit 1121 transmits the digital signal and the channel-select signal to the first signal conversion unit 1122 through a manner of burning program, and the signal configuration unit 1121 is used to replace a panel driving chip, reducing a demand for the panel driving chip. As such, the panel driving architecture is provided in the disclosure, which solves problems of extended lead times for driving chips or no supply of driving chips due to a driving chip shortage, and increases a panel production efficiency.

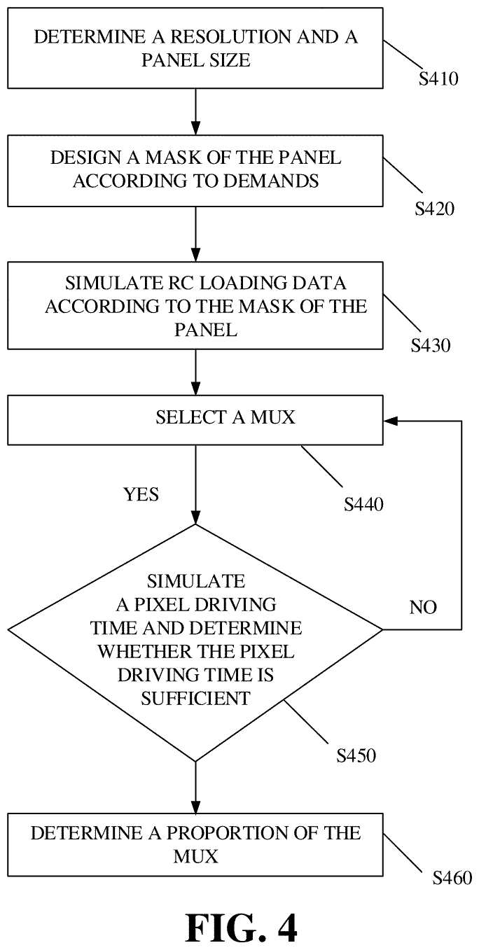

Referring to FIG. 4, FIG. 4 is a schematic diagram illustrating proportional selection logic of a signal transmission unit in the panel driving architecture illustrated in FIG. 2. In the implementations of the disclosure, a proportional selection method of the signal transmission units 1231 includes at least the following.

At S410, a resolution and a panel size are determined.

At S420, a mask of the panel is designed according to demands.

At S430, RC Loading data is simulated according to the mask of the panel.

At S440, a MUX is selected.

In an implementation, the MUX can be selected from 1:1 MUX, 1:2 MUX . . . 1:N MUX.

At S450, a pixel driving time is simulated and whether the pixel driving time is sufficient is determined.

In an implementation, if it is determined that the pixel driving time is insufficient, the method returns to S440; and if it is determined that the pixel driving time is sufficient, the method proceeds to S460. In specific examples, a driving time of a pixel at the maximal distal is first simulated by a design software based on the highest order MUX, and then whether the driving time is sufficient is determined. In practice, a proportion of the MUX used in the first simulation can be selected according to experience. If it is determined that the pixel driving time is insufficient, a lower order MUX is selected until the pixel driving time is sufficient.

At S460, a proportion of the MUX is determined.

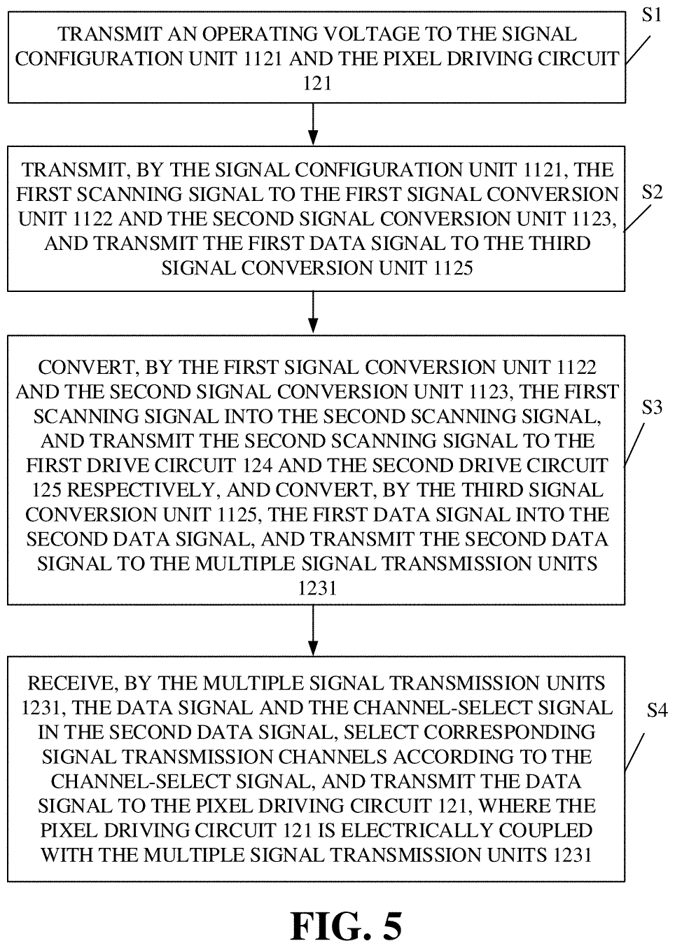

Referring to FIG. 5, FIG. 5 is a schematic flow chart of a driving method for a panel driving architecture disclosed in the implementations of the disclosure. The driving method for a panel driving architecture illustrated in FIG. 5 is applied to the panel driving architecture illustrated in FIGS. 1 to 3. The method is used to solve problems of extended lead times of driving chips or no supply of driving chips due to a driving chip shortage, by using the FPGA to replace the panel driving chip. It to be noted that, the driving method for a panel driving architecture in the implementations of the disclosure is not limited to the steps and sequences in the flow chart illustrated in FIG. 5. The steps in the flow chart illustrated can be added, removed, or changed in sequence according to different needs. In the implementations of the disclosure, the driving method for a panel driving architecture includes at least the following.

At S1, the power management circuit 111 transmits an operating voltage to the signal configuration unit 1121 and the pixel driving circuit 121.

Specifically, in the implementation, the power management circuit 111 transmits the operating voltage to the pixel driving circuit 121 and the signal configuration unit 1121. In the implementation, the power management circuit 111 may be a PMIC, and can provide an ELVDD or an ELVSS for the panel module 120 and provide the operating voltage for the signal management circuit 112.

At S2, the signal configuration unit 1121 transmits the first scanning signal to the first signal conversion unit 1122 and the second signal conversion unit 1123, and transmits the first data signal to the third signal conversion unit 1125.

Specifically, in the implementation, the signal configuration unit 1121 is configured to: provide the first scanning signal, transmit the first scanning signal to the first signal conversion unit 1122 and the second signal conversion unit 1123, provide the first data signal, and transmit the first data signal to the third signal conversion unit 1125. Each of the first scanning signal and the first data signal is a digital signal.

In the implementations of the disclosure, the signal configuration unit 1121 may be an FPGA. In specific applications, the signal configuration unit 1121 provides the digital signal and the channel-select signal for the first signal conversion unit 1122, the second signal conversion unit 1123, and the third signal conversion unit 1125 through a manner of burning program.

At S3, the first signal conversion unit 1122 and the second signal conversion unit 1123 convert the first scanning signal into the second scanning signal, and transmit the second scanning signal to the first drive circuit 124 and the second drive circuit 125 respectively. The third signal conversion unit 1125 converts the first data signal into the second data signal, and transmits the second data signal to the multiple signal transmission units 1231.

Specifically, in the implementation, the first signal conversion unit 1122 converts the first scanning signal transmitted by the signal configuration unit 1121 into the second scanning signal, and outputs the second scanning signal to the first drive circuit 124. The second signal conversion unit 1123 converts the first scanning signal transmitted by the signal configuration unit 1121 into the second scanning signal, and outputs the second scanning signal to the second drive circuit 125.

In the implementations of the disclosure, each of the first signal conversion unit 1122 and the second signal conversion unit 1123 may be a DAC.

Specifically, in the implementation, the third signal conversion unit 1125 converts the first data signal transmitted by the signal configuration unit 1121 into the second data signal, and outputs the second data signal to the multiple signal transmission units 1231.

In the implementations of the disclosure, the third signal conversion unit 1125 includes multiple DACs. In the implementations of the disclosure, the number of the DACs in the third signal conversion unit 1125 corresponds to the number of the signal transmission units 1231, and each DAC in the third signal conversion unit 1125 is electrically coupled with one corresponding signal transmission unit 1231.

In the implementations of the disclosure, each of the second scanning signal and the second data signal is an analog signal. The second scanning signal includes but is not limited to: an STV signal and a CLK signal. The second data signal includes but is not limited to: a data signal (i.e., an RGB data signal) and a channel-select signal.

At S4, the multiple signal transmission units 1231 receive the data signal and the channel-select signal in the second data signal, select corresponding signal transmission channels according to the channel-select signal, and transmit the data signal to the pixel driving circuit 121, where the pixel driving circuit 121 is electrically coupled with the multiple signal transmission units 1231.

Specifically, in the implementation, each of the multiple signal transmission units 1231 receives the data signal and the channel-select signal transmitted by the third signal conversion unit 1125, selects corresponding signal transmission channels according to the channel-select signal, and transmits the data signal to the pixel driving circuit 121 through different lines. In this case, the pixel driving circuit 121 receives the data signal transmitted by the signal transmission circuit 123, and drives the RGB pixels to display corresponding brightness according to the signal.

It can be seen that, in the driving method for a panel driving architecture provided in the disclosure, the signal configuration unit 1121 transmits the digital signal and the channel-select signal to the first signal conversion unit 1122 through a manner of programing. The FPGA is used to replace a panel driving chip, reducing a demand for the panel driving chip. As such, the panel driving architecture is provided in the disclosure, which solves problems of extended lead times for driving chips or no supply of driving chips due to a driving chip shortage, and increases a panel production efficiency.

A display device is further provided in the implementations of the disclosure. The display device includes a display panel and the panel driving architecture illustrated in FIGS. 1 to 3. The display panel includes a display area and a non-display area, where the display area is for image display, and the non-display area is around the display area and not for image display. The display panel can use a liquid crystal material as a display medium, which is not limited herein. The display device may be a liquid crystal display device or an electroluminescent display device, such as an organic LED (OLED) panel, a micro LED panel, a mini LED panel, a phone, a tablet computer, a navigator, a display, or any electrical devices or assemblies with a display function, which is not limited herein.

It should be understood that the disclosure is not to be limited to the above-identified implementations. Those of ordinary skill in the art can make improvements or changes based on the above description, and all these improvements and changes should fall within the protection scope of the appended claims of the disclosure.

What is claimed is:

1. A panel driving architecture, comprising:
a circuit board module comprising a power management circuit and a signal management circuit; and
a panel module electrically coupled with the circuit board module, wherein
the power management circuit is electrically coupled with the panel module and the signal management circuit and configured to provide an operating voltage for the panel module and the signal management circuit;
the signal management circuit is electrically coupled with the panel module and configured to:
provide a first scanning signal;
convert the first scanning signal into a second scanning signal;
output the second scanning signal to the panel module;
provide a first data signal;
convert the first data signal into a second data signal containing a data signal; and
output the second data signal to the panel module; and
the panel module is configured to drive pixels to display according to the data signal.

2. The panel driving architecture of claim 1, wherein
the signal management circuit comprises a signal configuration unit, a first signal conversion unit, a second signal conversion unit, and a third signal conversion unit; and
the signal configuration unit is electrically coupled with the power management circuit, the first signal conversion unit, the second signal conversion unit, and the third signal conversion unit and configured to:
provide the first scanning signal;
transmit the first scanning signal to the first signal conversion unit and the second signal conversion unit;
provide the first data signal; and
transmit the first data signal to the third signal conversion unit.

3. The panel driving architecture of claim 2, wherein
the first signal conversion unit is electrically coupled between the signal configuration unit and the panel module and configured to convert the first scanning signal transmitted by the signal configuration unit into the second scanning signal, and output the second scanning signal to the panel module;
the second signal conversion unit is electrically coupled between the signal configuration unit and the panel module and configured to convert the first scanning signal transmitted by the signal configuration unit into the second scanning signal, and output the second scanning signal to the panel module; and
the third signal conversion unit is electrically coupled between the signal configuration unit and the panel module and configured to convert the first data signal transmitted by the signal configuration unit into the second data signal, and output the second data signal to the panel module.

4. The panel driving architecture of claim 2, wherein the signal configuration unit is a field-programmable gate array (FPGA).

5. The panel driving architecture of claim 2, wherein
each of the first signal conversion unit, the second signal conversion unit, and the third signal conversion unit is a digital-to-analog convertor (DAC);
each of the first scanning signal and the first data signal is a digital signal; and
each of the second scanning signal and the second data signal is an analog signal.

6. The panel driving architecture of claim 2, wherein
the panel module comprises a pixel driving circuit and a signal transmission circuit; and
the signal transmission circuit is electrically coupled between the pixel driving circuit and the signal management circuit and configured to:
receive the second data signal which is transmitted by the signal management circuit and contains the data signal and a channel-select signal;
select corresponding signal transmission channels according to the channel-select signal; and
transmit the data signal to the pixel driving circuit.

7. The panel driving architecture of claim 6, wherein
the panel module further comprises a first drive circuit and a second drive circuit; and
each of the first drive circuit and the second drive circuit is electrically coupled with the pixel driving circuit and the signal management circuit and configured to:
transmit a corresponding drive signal to the pixel driving circuit; and
receive the second scanning signal outputted from the signal management circuit.

8. The panel driving architecture of claim 7, wherein each of the first drive circuit and the second drive circuit consists of a gate driver on array (GOA) circuit and an emission driver on array (EOA) circuit.

9. The panel driving architecture of claim 6, wherein
the signal transmission circuit comprises a plurality of signal transmission units; and
each of the plurality of signal transmission units is electrically coupled between the third signal conversion unit and the pixel driving circuit and configured to:
receive the data signal and the channel-select signal transmitted by the third signal conversion unit;
select corresponding signal transmission channels according to the channel-select signal; and
transmit the data signal to the pixel driving circuit.

10. The panel driving architecture of claim 9, wherein each of the plurality of signal transmission units is a multiplexer (MUX).

11. A driving method for a panel driving architecture, wherein
the panel driving architecture, comprising:
a circuit board module comprising a power management circuit and a signal management circuit; and
a panel module electrically coupled with the circuit board module, wherein
the power management circuit is electrically coupled with the panel module and the signal management circuit and configured to provide an operating voltage for the panel module and the signal management circuit;
the signal management circuit is electrically coupled with the panel module and configured to:
provide a first scanning signal;
convert the first scanning signal into a second scanning signal;
output the second scanning signal to the panel module;
provide a first data signal;
convert the first data signal into a second data signal containing a data signal; and
output the second data signal to the panel module; and
the panel module is configured to drive pixels to display according to the data signal; and
the driving method is for driving the panel driving architecture and comprises:
transmitting, by the power management circuit, an operating voltage to the signal configuration unit and the pixel driving circuit;
transmitting, by the signal configuration unit, the first scanning signal to the first signal conversion unit and the second signal conversion unit;
transmitting, by the signal configuration unit, the first data signal to the third signal conversion unit;
converting, by the first signal conversion unit and the second signal conversion unit, the first scanning signal into the second scanning signal;
transmitting, by the first signal conversion unit and the second signal conversion unit, the second scanning signal to the first drive circuit and the second drive circuit respectively;
converting, by the third signal conversion unit, the first data signal into the second data signal containing the data signal and the channel-select signal;
transmitting, by the third signal conversion unit, the second data signal to the plurality of signal transmission units;
receiving, by the plurality of signal transmission units, the data signal and the channel-select signal in the second data signal;
selecting, by the plurality of signal transmission units, corresponding signal transmission channels according to the channel-select signal; and
transmitting, by the plurality of signal transmission units, the data signal to the pixel driving circuit, wherein the pixel driving circuit is electrically coupled with the plurality of signal transmission units.

12. A display device, comprising:
a display panel; and
a panel driving architecture comprising a circuit board module and a panel module electrically coupled with the circuit board module, the circuit board module comprising a power management circuit and a signal management circuit, wherein
the power management circuit is electrically coupled with the panel module and the signal management circuit and configured to provide an operating voltage for the panel module and the signal management circuit;
the signal management circuit is electrically coupled with the panel module and configured to:
provide a first scanning signal;
convert the first scanning signal into a second scanning signal;
output the second scanning signal to the panel module;
provide a first data signal;
convert the first data signal into a second data signal containing a data signal; and
output the second data signal to the panel module; and
the panel module is configured to drive pixels to display according to the data signal.

13. The display device of claim 12, wherein
the signal management circuit comprises a signal configuration unit, a first signal conversion unit, a second signal conversion unit, and a third signal conversion unit; and
the signal configuration unit is electrically coupled with the power management circuit, the first signal conversion unit, the second signal conversion unit, and the third signal conversion unit and configured to:
provide the first scanning signal;
transmit the first scanning signal to the first signal conversion unit and the second signal conversion unit;
provide the first data signal; and
transmit the first data signal to the third signal conversion unit.

14. The display device of claim 13, wherein
the first signal conversion unit is electrically coupled between the signal configuration unit and the panel module and configured to convert the first scanning signal transmitted by the signal configuration unit into the second scanning signal, and output the second scanning signal to the panel module;
the second signal conversion unit is electrically coupled between the signal configuration unit and the panel module and configured to convert the first scanning signal transmitted by the signal configuration unit into the second scanning signal, and output the second scanning signal to the panel module; and
the third signal conversion unit is electrically coupled between the signal configuration unit and the panel module and configured to convert the first data signal transmitted by the signal configuration unit into the second data signal, and output the second data signal to the panel module.

15. The display device of claim 13, wherein the signal configuration unit is a field-programmable gate array (FPGA).

16. The display device of claim 13, wherein
each of the first signal conversion unit, the second signal conversion unit, and the third signal conversion unit is a digital-to-analog convertor (DAC);
each of the first scanning signal and the first data signal is a digital signal; and
each of the second scanning signal and the second data signal is an analog signal.

17. The display device of claim 13, wherein
the panel module comprises a pixel driving circuit and a signal transmission circuit; and
the signal transmission circuit is electrically coupled between the pixel driving circuit and the signal management circuit and configured to:
receive the second data signal which is transmitted by the signal management circuit and contains the data signal and a channel-select signal;
select corresponding signal transmission channels according to the channel-select signal; and
transmit the data signal to the pixel driving circuit.

18. The display device of claim 17, wherein
the panel module further comprises a first drive circuit and a second drive circuit; and
each of the first drive circuit and the second drive circuit is electrically coupled with the pixel driving circuit and the signal management circuit and configured to:
transmit a corresponding drive signal to the pixel driving circuit; and
receive the second scanning signal outputted from the signal management circuit.

19. The display device of claim 18, wherein each of the first drive circuit and the second drive circuit consists of a gate driver on array (GOA) circuit and an emission driver on array (EOA) circuit.

20. The display device of claim 17, wherein
the signal transmission circuit comprises a plurality of signal transmission units; and
each of the plurality of signal transmission units is electrically coupled between the third signal conversion unit and the pixel driving circuit and configured to:
receive the data signal and the channel-select signal transmitted by the third signal conversion unit;
select corresponding signal transmission channels according to the channel-select signal; and
transmit the data signal to the pixel driving circuit.
